(19) United States
(12) Patent Application Publication
(10) Pub. No.: US 2025/0159928 A1
(43) Pub. Date: May 15, 2025

(54) TRANSISTOR DEVICE HAVING GATE STRUCTURE WITH ISOLATION REGION THEREIN, AND RELATED FABRICATION METHOD

(71) Applicant: Samsung Electronics Co., Ltd., Suwon-si (KR)

(72) Inventors: Seungchan Yun, Waterford, NY (US); Kang-Ill Seo, Springfield, VA (US)

(21) Appl. No.: 18/732,713

(22) Filed: Jun. 4, 2024

Related U.S. Application Data
(60) Provisional application No. 63/548,087, filed on Nov. 10, 2023.

(51) Int. Cl. H01L 29/417; H01L 21/822; H01L 21/8238; H01L 27/06; H01L 27/092; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 64/017; H10D 84/0167; H10D 84/017; H10D 84/0188; H10D 84/038; H10D 84/856; H10D 88/00; H10D 88/01

(57) ABSTRACT

Stacked field-effect transistor (FET) devices are provided. A stacked FET device includes a lower FET having a lower gate structure. The stacked FET device includes a contact that is electrically connected to the lower FET. The stacked FET device includes an upper FET that is on top of the lower FET. The upper FET includes an upper gate structure that includes a conductive gate and an isolation region that is in the conductive gate and on a sidewall of the contact. Moreover, the stacked FET device includes an insulating layer that is between a lower surface of the isolation region and an upper surface of the lower gate structure. Related methods of forming stacked FET devices are also provided.

### RELATED APPLICATIONS

The present application claims the benefit of U.S. Provisional Patent Application Ser. No. 63/548,087, filed on Nov. 10, 2023, entitled SEMICONDUCTOR DEVICE FORMED FROM TRI-LAYER DUMMY GATE STRUCTURE TO HAVE REDUCED PARASITIC CAPACITANCE, the disclosure of which is hereby incorporated herein in its entirety by reference.

### TECHNICAL FIELD

The present disclosure generally relates to the field of semiconductor devices and, more particularly, to three-dimensional transistor structures.

### BACKGROUND OF THE INVENTION

The size of transistors in integrated circuit (IC) devices has continued to decrease to down-scale logic elements. This has resulted in the development of gate-all-around (GAA) structures such as multi-bridge channel field-effect transistors (MBCFETs™) and nanosheet FETs (NSFETs). Moreover, as technology to increase transistor density has continued to develop, three-dimensional device structures, such as stacked transistors, are under consideration.

A stacked transistor may include a first transistor and a second transistor. The first transistor may be a first type of transistor (e.g., an n-type metal-oxide-semiconductor (NMOS) transistor) and the second transistor may be a second type of transistor (e.g., a p-type metal-oxide-semiconductor (PMOS) transistor). The first and second types of transistors may be complementary to each other, and thus may be part of a complementary metal-oxide-semiconductor (CMOS) IC. The first and second transistors may be stacked in any order (e.g., first on top of second, or second on top of first), thereby resulting in a stack comprising a top/upper transistor and a bottom/lower transistor.

### SUMMARY OF THE INVENTION

A stacked FET, according to some embodiments herein, may include a lower FET having lower channel layers, a lower gate structure that is between the lower channel layers, and a lower source/drain (S/D) region that is electrically connected to the lower channel layers. The stacked FET device may include an S/D contact that is electrically connected to the lower S/D region. The stacked FET device may include an upper FET that is on top of the lower FET. The upper FET may include upper channel layers, an upper gate structure that is between the upper channel layers, and an upper S/D region that is electrically connected to the upper channel layers. The upper gate structure may include a conductive gate and an isolation region that is inside the conductive gate and on a sidewall of the S/D contact. The stacked FET device may include a spacer that separates the upper channel layers from the lower channel layers. Moreover, the stacked FET device may include an insulating layer that is between a lower surface of the isolation region and an upper surface of the lower gate structure.

A stacked FET, according to some embodiments herein, may include a lower FET including lower channel layers and a lower gate structure that is between the lower channel layers. The stacked FET may include a contact that is electrically connected to the lower FET. The stacked FET may include an upper FET that is on top of the lower FET. The upper FET may include upper channel layers and an upper gate structure that is between the upper channel layers. The upper gate structure may include a conductive gate and an isolation region that is between a first portion and a second portion of the conductive gate and on a sidewall of the contact. The stacked FET may include a spacer that separates the upper channel layers from the lower channel layers. Moreover, the stacked FET may include an insulating layer that is between a lower surface of the isolation region and an upper surface of the lower gate structure.

A method of forming a stacked FET device, according to some embodiments herein, may include forming a nanosheet stack and a multi-layer dummy gate structure on the nanosheet stack. The multi-layer dummy gate structure may include a lower semiconductor sacrificial layer, an upper semiconductor sacrificial layer, and an etch-stop layer that is between the lower semiconductor sacrificial layer and the upper semiconductor sacrificial layer. The method may include etching the upper semiconductor sacrificial layer to expose sidewalls of the upper semiconductor sacrificial layer. The method may include forming a first insulating layer comprising vertical portions on the exposed sidewalls of the upper semiconductor sacrificial layer and a lateral portion between upper nanosheets of the nanosheet stack and lower nanosheets of the nanosheet stack. The method may include patterning the upper semiconductor sacrificial layer by removing a portion of the upper semiconductor sacrificial layer that is between the vertical portions of the first insulating layer and exposing an upper surface of the etch-stop layer, wherein the etch-stop layer comprises a second insulating layer. The method may include forming an isolation region between the vertical portions of the first insulating layer and on the exposed upper surface of the etch-stop layer. Moreover, the method may include forming a contact on a sidewall of one of the vertical portions of the first insulating layer. The vertical portions of the first insulating layer may extend longitudinally in a vertical direction that is perpendicular to the exposed upper surface of the etch-stop layer.

### BRIEF DESCRIPTION OF THE DRAWINGS

FIG. 1A is a schematic block diagram of a transistor stack of a transistor device according to some embodiments herein.

FIG. 1B is an example plan view of the transistor device of FIG. 1A.

FIG. 1C is an example cross-sectional view of the transistor device of FIG. 1B along the line A-A′.

FIG. 1D is an example cross-sectional view of the transistor device of FIG. 1B along the line B-B′.

FIG. 1E is an example cross-sectional view of the transistor device of FIG. 1B along the line C-C′.

FIGS. 2A-2W are cross-sectional views illustrating operations of forming the transistor device of FIGS. 1C-1E.

FIG. 3 is a flowchart corresponding to the operations shown in FIGS. 2A-2W.

### DETAILED DESCRIPTION

As stacked FET devices have developed, gates of the devices have increased in height. A stacked FET device may include a gate and a contact (e.g., an S/D contact) that is adjacent the gate, where the gate and the contact are both conductive (e.g., metal). Increased height of the gate can thus increase parasitic capacitance between the gate and the contact. For example, the contact of the stacked FET device may be a relatively deep (e.g., relatively tall) contact that is electrically connected to a lower FET of the stacked FET device, and the contact may be susceptible to having a parasitic capacitance between it and metal of an adjacent relatively tall upper gate. Moreover, attempting to reduce the parasitic capacitance by recessing a portion of the upper gate and replacing the recess with an isolation region (e.g., a low-k material) can result in an undesirable process variation with respect to a depth of the recess and, if the recess is too deep, a lower channel layer of the stacked FET device can be damaged.

Pursuant to embodiments herein, however, transistor devices are provided that include upper gate structures having isolation regions therein. An isolation region in an upper gate structure of a stacked FET device may be adjacent a relatively tall contact and may occupy a space that would otherwise be occupied by a conductive portion of the upper gate structure. As a result, the isolation region can reduce parasitic capacitance between the contact and the gate structure, and can thereby improve performance of the stacked FET device.

In some embodiments, the isolation region may be formed on an etch-stop layer of a multi-layer dummy gate structure. The etch-stop layer can improve control over a recess process for the multi-layer dummy gate structure, and thus can reduce the likelihood of damaging a lower channel layer of the stacked FET device during the recess process.

Example embodiments will be described in greater detail with reference to the attached figures.

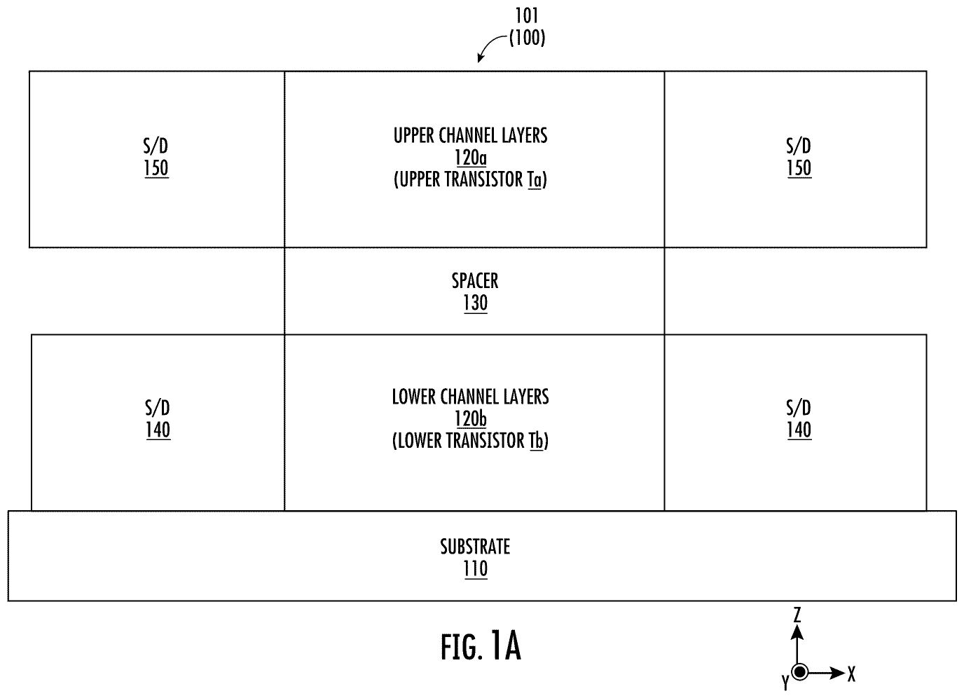

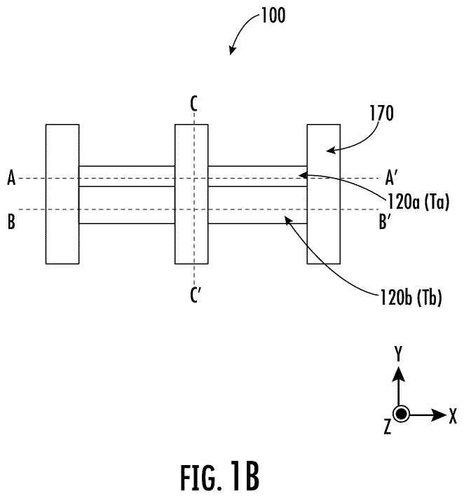

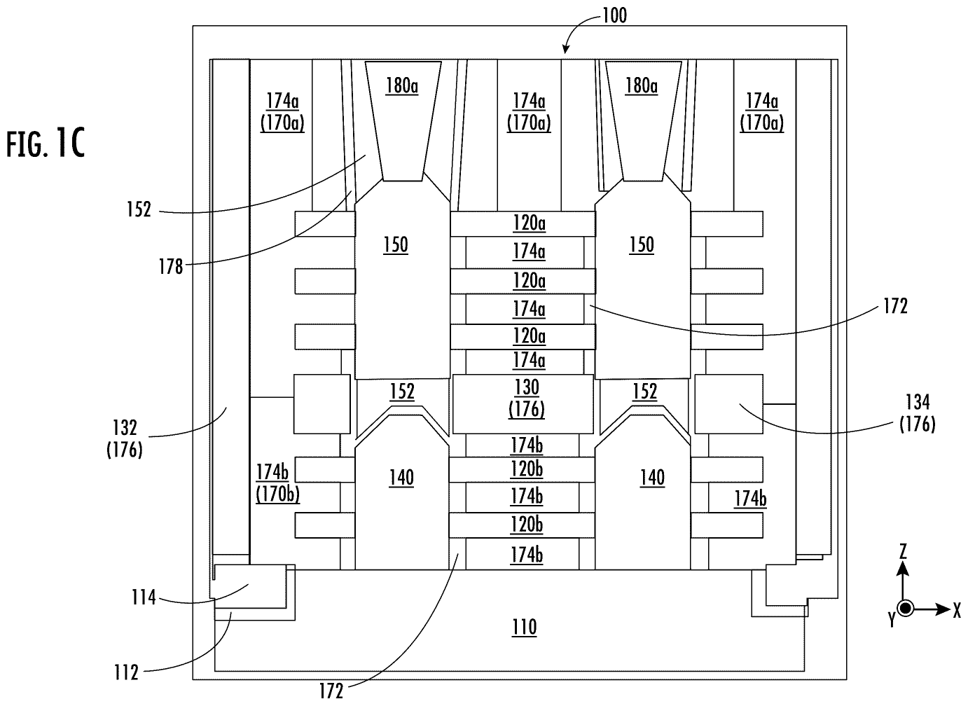

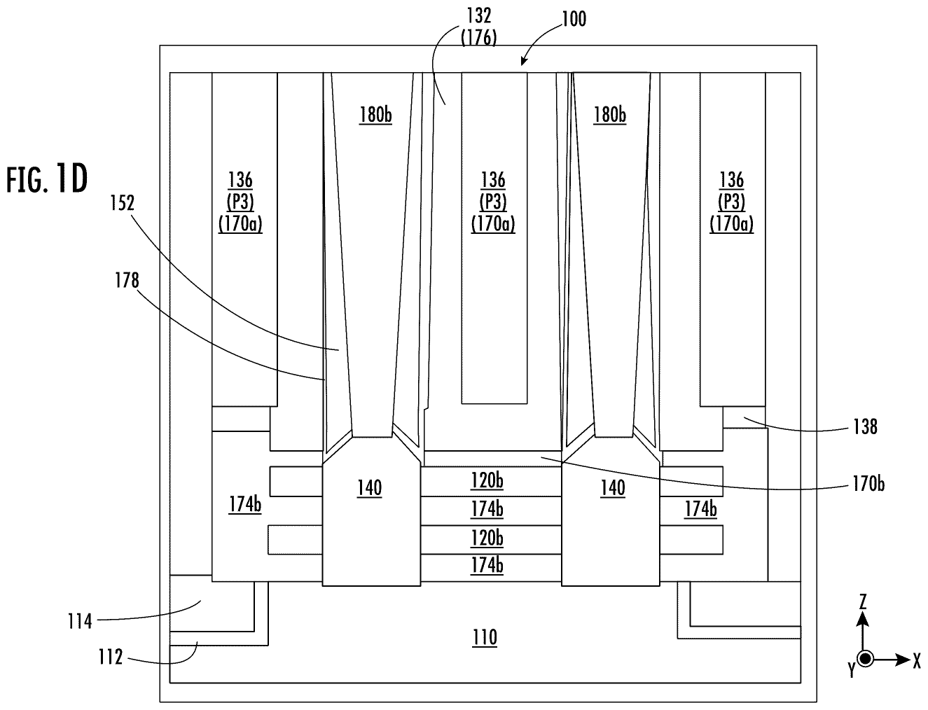

FIG. 1A is a schematic block diagram of a transistor stack 101 of a transistor device 100 according to some embodiments herein. The transistor stack 101 includes a lower transistor Tb having a stack of lower semiconductor channel layers 120b and an upper transistor Ta having a stack of upper semiconductor channel layers 120a. The channel layers 120a, 120b may comprise, for example, silicon and may be free of germanium and carbon. The lower transistor Tb is between, in a vertical direction Z, the upper transistor Ta and a substrate 110 (e.g., a silicon, or other semiconductor, substrate). Moreover, an isolation layer 130, such as a middle dielectric isolation (MDI) layer, may, in some embodiments, serve as a spacer between the lower and upper transistors Ta, Tb. The isolation layer 130 may thus be referred to herein as a “spacer.”

The lower channel layers 120b of the lower transistor Tb are between, in a first horizontal (i.e., lateral) direction X, a pair of lower S/D regions 140 that are electrically connected to the lower channel layers 120b. The first horizontal direction X and the vertical direction Z may be perpendicular to each other, and a second horizontal (i.e., lateral) direction Y may be perpendicular to each of the first horizontal direction X and the vertical direction Z. Each lower channel layer 120b may be implemented by, for example, a nanosheet or nanowire between the lower S/D regions 140. Likewise, the upper channel layers 120a of the upper transistor Ta may be between, in the first horizontal direction X, a pair of upper S/D regions 150 that are electrically connected to the upper channel layers 120a, and each upper channel layer 120a may be implemented by, for example, a nanosheet or nanowire between the upper S/D regions 150.

In some embodiments, the upper S/D regions 150 may include a different semiconductor material from that of the lower S/D regions 140. As an example, the upper S/D regions 150 may include silicon germanium, and the lower S/D regions 140 may include silicon carbide, or vice versa. In other embodiments, the upper S/D regions 150 may include the same semiconductor material as the lower S/D regions 140.

For simplicity of illustration, only one transistor stack 101 is shown in FIG. 1A. According to some embodiments, however, the device 100 may include two, three, four, or more transistor stacks 101.

FIG. 1B is an example plan view of the transistor device 100. As shown in FIG. 1B, the device 100 includes one or more gate structures 170 on the upper channel layers 120a of the upper transistor Ta and the lower channel layers 120b of the lower transistor Tb. A line A-A′ extends along a channel width of the upper channel layers 120a of the upper transistor Ta in the lateral direction X. A line B-B′ extends along a channel width of the lower channel layers 120b of the lower transistor Tb in the lateral direction X. The lines A-A′ and B-B′ are spaced apart from each other in the other lateral direction Y. A line C-C′ passes lengthwise (i.e., longitudinally) through a gate structure 170 in the other lateral direction Y.

FIG. 1C is an example cross-sectional view of the transistor device 100 along the line A-A′ of FIG. 1B. As shown in FIG. 1C, an upper gate structure 170a may be on the upper channel layers 120a of the upper transistor Ta of the transistor stack 101 (FIG. 1A), and a lower gate structure 170b may be on the lower channel layers 120b of the lower transistor Tb (FIG. 1B) of the transistor stack 101. The upper gate structure 170a includes an upper conductive gate 174a that is segmented into portions (e.g., a first portion and a second portion) and an isolation region 136 (FIG. 1E) that is between the segmented portions of (e.g., inside) the upper conductive gate 174a. The upper conductive gate 174a may be between (in the vertical direction Z) the upper channel layers 120a, and may be spaced apart from the upper S/D regions 150 in the direction X by insulating spacers 172. The spacers 172 may be on sidewalls of the upper conductive gate 174a and between, in the vertical direction Z, the upper channel layers 120a.

Likewise, the lower gate structure 170b may include a lower conductive gate 174b that is between (in the vertical direction Z) the lower channel layers 120b. The lower conductive gate 174b may be spaced apart from the lower S/D regions 140 in the direction X by spacers 172, which may be on sidewalls of the lower conductive gate 174b and between, in the vertical direction Z, the lower channel layers 120b. Unlike the upper conductive gate 174a, however, the lower conductive gate 174b may not have an isolation region therein. In some embodiments, the spacers 172 may contact the lower S/D regions 140, the upper S/D regions 150, sidewalls of the lower conductive gate 174b, and sidewalls of the upper conductive gate 174a. Sidewalls of the lower channel layers 120b may contact the lower S/D regions 140, and sidewalls of the upper channel layers 120a may contact the upper S/D regions 150.

The upper conductive gate 174a and the lower conductive gate 174b may each include a metal or a semiconductor material. As an example, the upper conductive gate 174a and the lower conductive gate 174b may comprise different metals, respectively. Moreover, the spacers 172 may comprise, for example, nitrogen (e.g., silicon nitride). The spacers 172 may also be referred to herein as “inner spacers,” as they may be situated between nanosheet/nanowire channels within a transistor.

The upper and lower transistors Ta, Tb may be different types of MOSFETs. The transistor device 100 may thus be a stacked FET device. For example, the upper and lower transistors Ta, Tb may be PMOS and NMOS transistors, respectively, or vice versa. As an example, PMOS and NMOS transistors may be provided by S/D regions comprising silicon germanium and silicon carbide, respectively. In some embodiments, the isolation layer 130 may be a spacer that separates the lower channel layers 120b of the lower transistor Tb from the upper channel layers 120a of the upper transistor Ta. The spacer 130 may comprise, for example, silicon boron carbonitride (SiBCN).

For simplicity of illustration, a gate insulation layer is omitted from view in FIG. 1C. It will be understood, however, that a gate insulation layer may extend between each channel layer 120 and a conductive gate 174. The gate insulation layer may wrap around each channel layer 120 and may be thinner than the spacer 130.

According to some embodiments, an insulating layer 112 may be in a recess of the substrate 110. An insulating layer 114 may also be in the recess, and may extend above the substrate 110 to, for example, a level of an uppermost surface of the upper gate structure 170a. An insulating layer 152 may be between, in the vertical direction Z, the lower and upper S/D regions 140, 150. Moreover, the insulating layer 152 may be on an upper surface of each of the upper S/D regions 150. An insulating layer 132 may be on sidewalls of the gate structures 170a, 170b and an upper surface of the insulating layer 114, and an insulating layer 134 may be between the upper gate structure 170a and the lower gate structure 170b. An insulating layer 178 may be between the insulating layer 132 and the insulating layer 152, and between the insulating layer 134 and the insulating layer 152.

The insulating layers 132, 134 may comprise the same insulating material (e.g., SiBCN) as the spacer 130, and this insulating material may be different from an insulating material of the insulating layer 112 and different from an insulating material of the insulating layers 114, 152. For example, the insulating layers 132, 134 and the spacer 130 may each be part of an insulating structure/layer 176 (i.e., the same insulating material). As an example, vertical portions of insulating material 176 may be provided by the insulating layer 132, and lateral portions of the insulating material 176 may be provided by the spacer 130 and the insulating layer 134. The spacer 130 may thus be referred to herein as a “lateral portion” of the insulating material 176 that extends longitudinally (i.e., primarily) in a lateral (X or Y) direction, and the insulating layer 132 may be referred to herein as a “vertical portion” (or “vertical portions”) of the insulating material 176 that extends longitudinally in a vertical (Z) direction. In some embodiments, the insulating layer 112 may comprise a different insulating material from that of the insulating layers 114, 152. As an example, the insulating layer 112 may comprise a nitride (e.g., silicon nitride), and the insulating layers 114, 152 may each comprise an oxide (e.g., silicon oxide).

The device 100 may include one or more upper contacts 180a that are electrically connected to the upper transistor Ta. For example, each upper S/D region 150 may be electrically connected to an upper contact 180a. In some embodiments, a lower surface of each upper contact 180a may be in contact with an upper surface of an upper S/D region 150. The upper contacts 180a may be conductive (e.g., metal) contacts, and may be electrically isolated from the upper conductive gate 174a by the insulating layers 132, 152, and 178. As an example, the insulating layer 132 may be between, in the lateral direction X, the upper conductive gate 174a and an upper contact 180a, and the insulating layers 152, 178 may be between, in the lateral direction X, the insulating layer 132 and the upper contact 180a.

FIG. 1D is an example cross-sectional view of the transistor device 100 along the line B-B′ of FIG. 1B. As shown in FIG. 1D, the device 100 may include one or more lower contacts 180b that are electrically connected to the lower transistor Tb (FIG. 1A). For example, each lower S/D region 140 may be electrically connected to a lower contact 180b. In some embodiments, a lower surface of each lower contact 180b may be in contact with an upper surface of a lower S/D region 140. According to some embodiments, each lower contact 180b may be a middle-of-line (MOL) contact that electrically connects the lower transistor Tb to an interconnect of the device 100.

The lower contacts 180b may be conductive (e.g., metal) contacts, and may be electrically isolated from the upper conductive gate 174a by the isolation region 136 of the upper gate structure 170a, in addition to the insulating layers 132, 152, and 178. As an example, a portion P3 of the isolation region 136 may be between, in the lateral direction X, two vertical portions 132 of the insulating material 176 that are between two lower contacts 180b. In some embodiments, the upper conductive gate 174a may not be between, in the lateral direction X, the two lower contacts 180b. Moreover, the isolation region 136 may be separated, in the lateral direction X, from a lower contact 180b by the insulating layers 152, 178, where the insulating layer 152 may be between, in the lateral direction X, the insulating layer 178 and the upper contact 180a. Accordingly, the isolation region 136 may be on a sidewall of the lower S/D contact 180b, with the insulating layers 132, 152, and 178 therebetween.

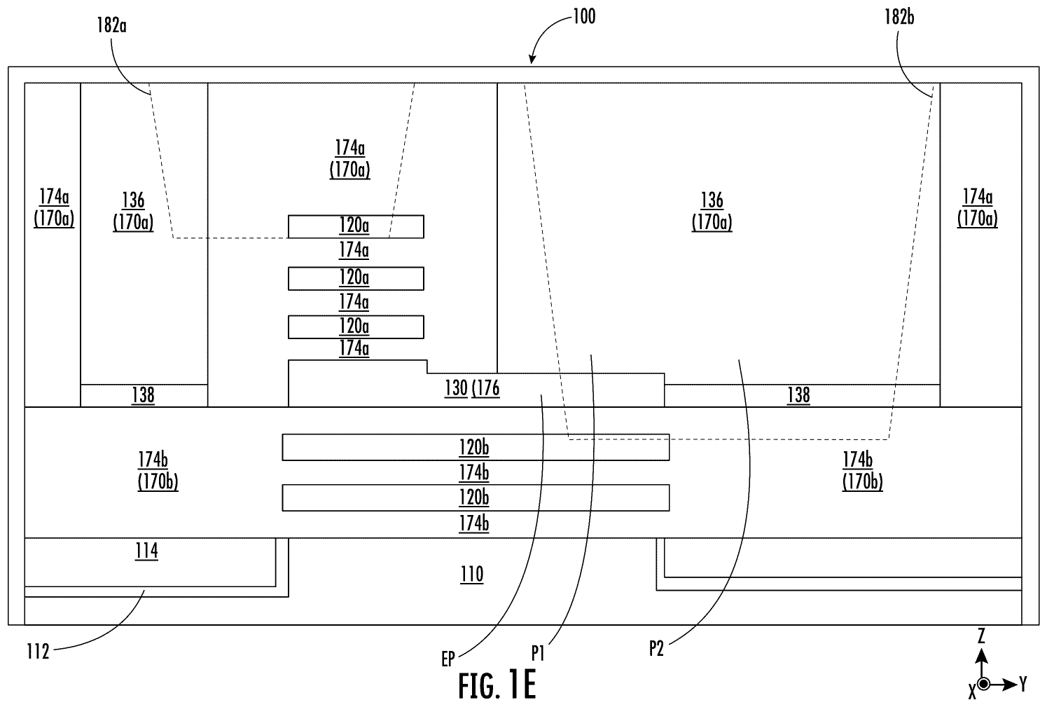

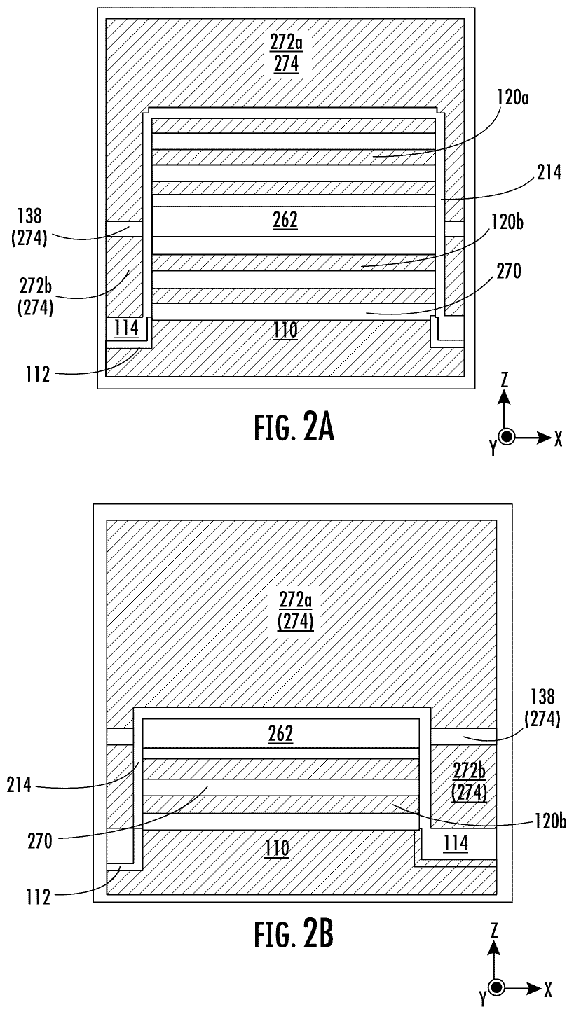

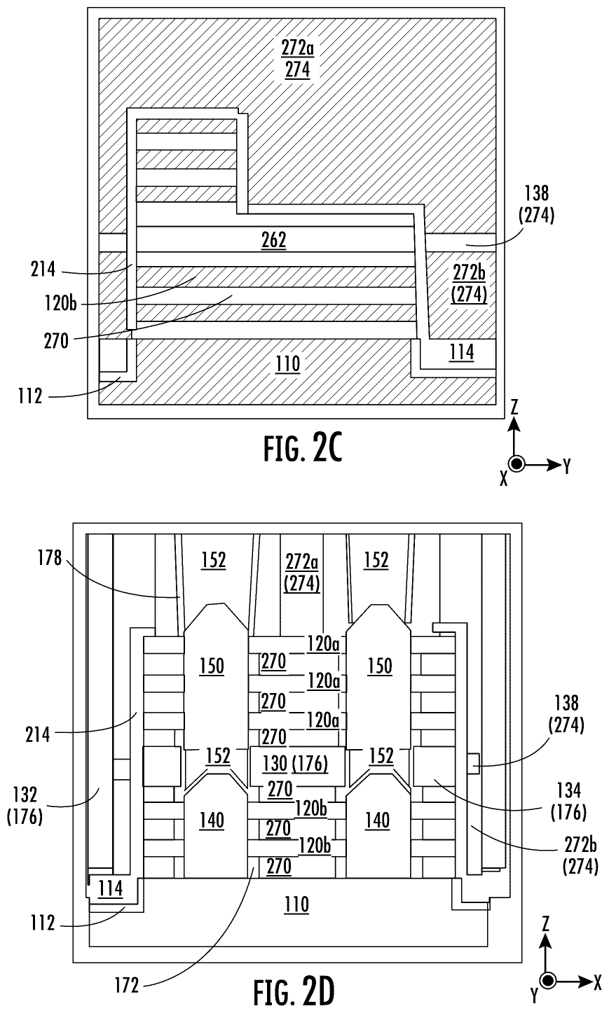

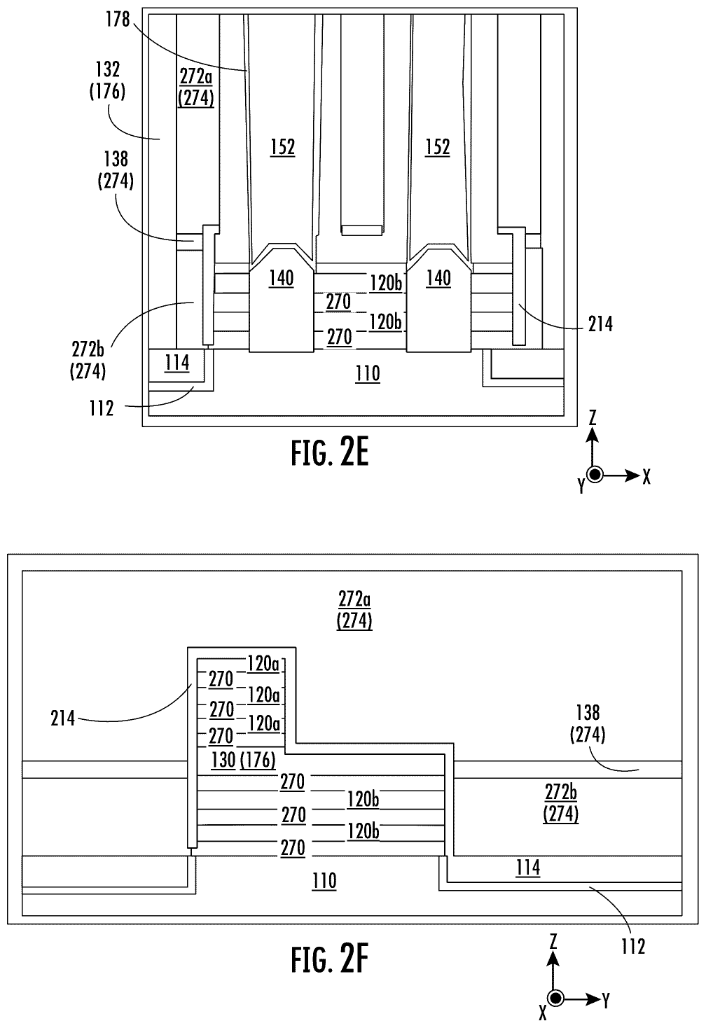

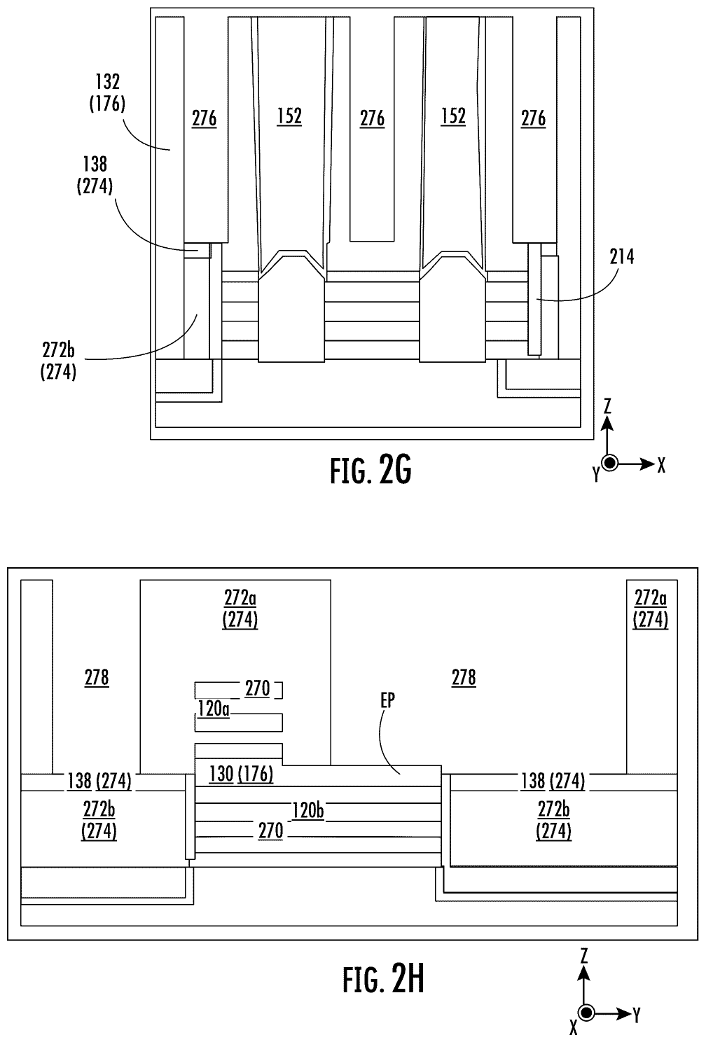

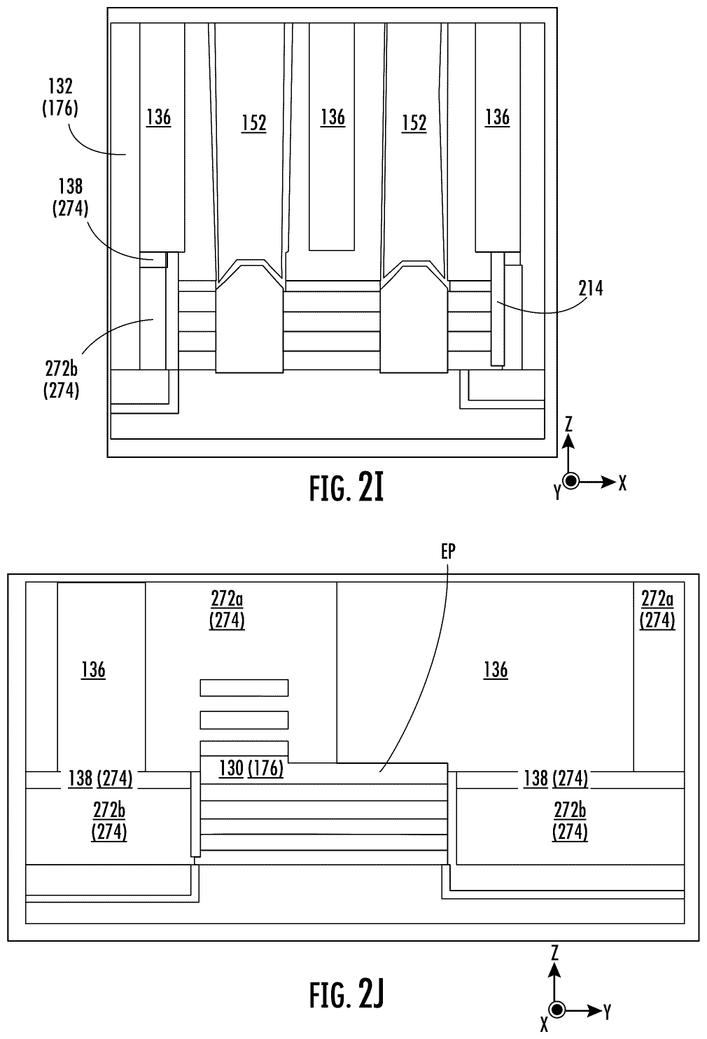

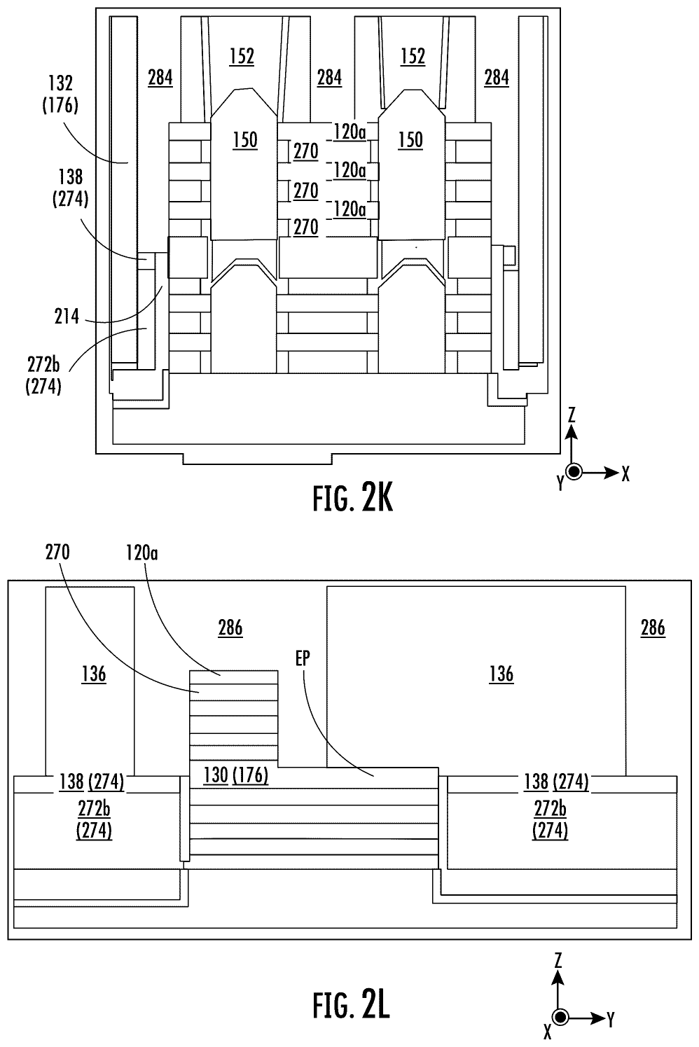

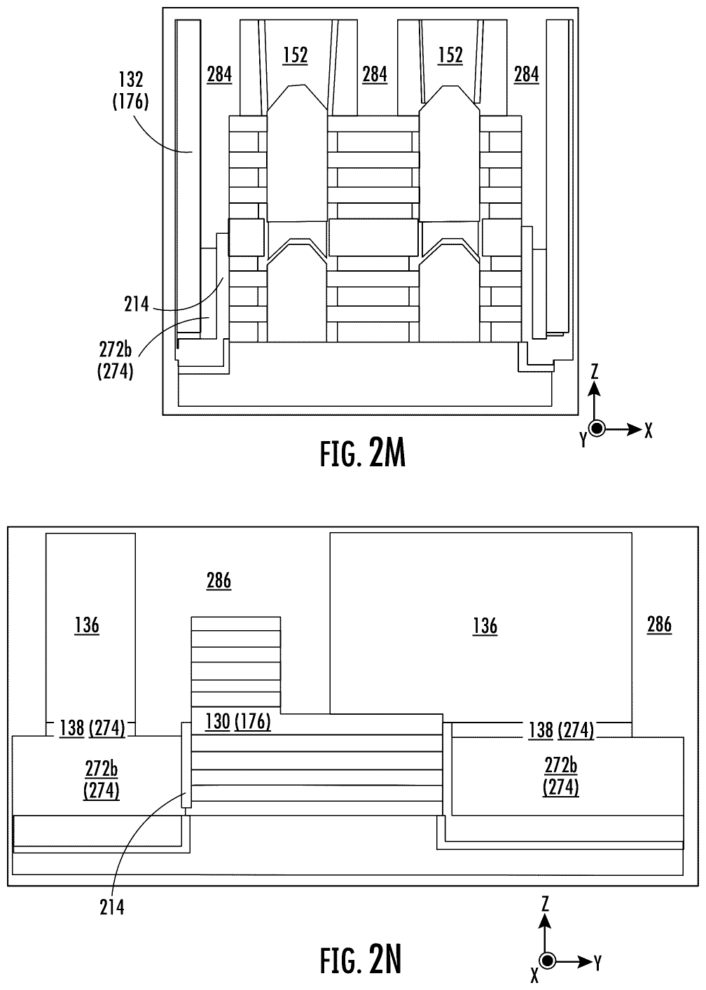

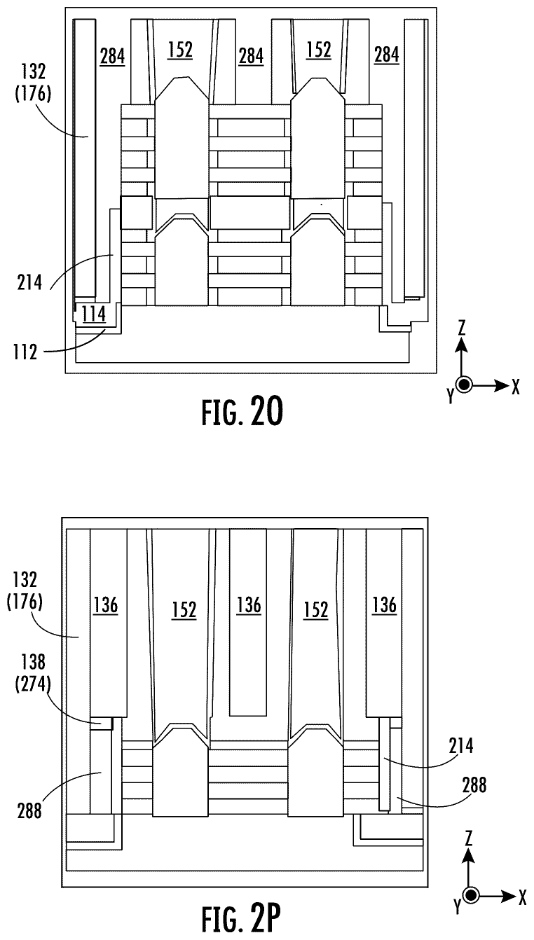

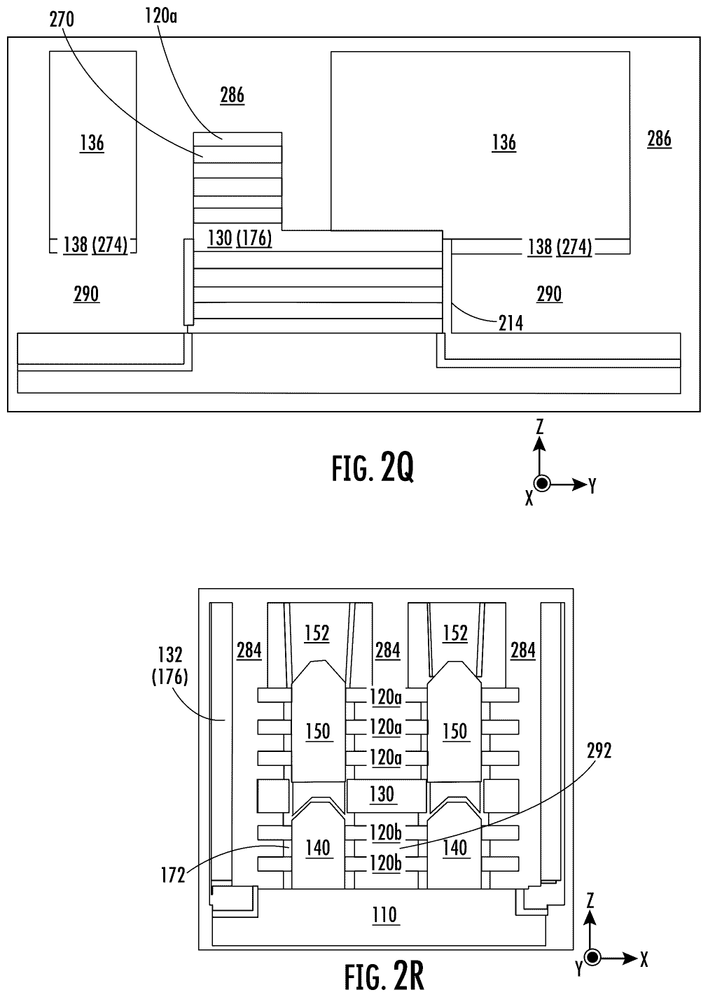

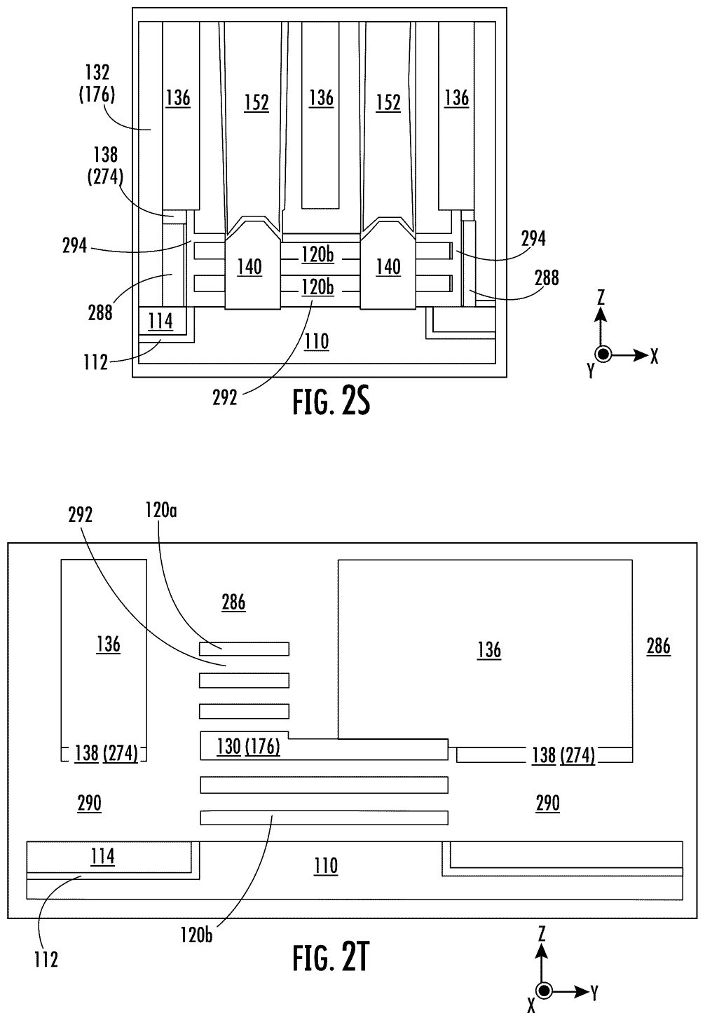

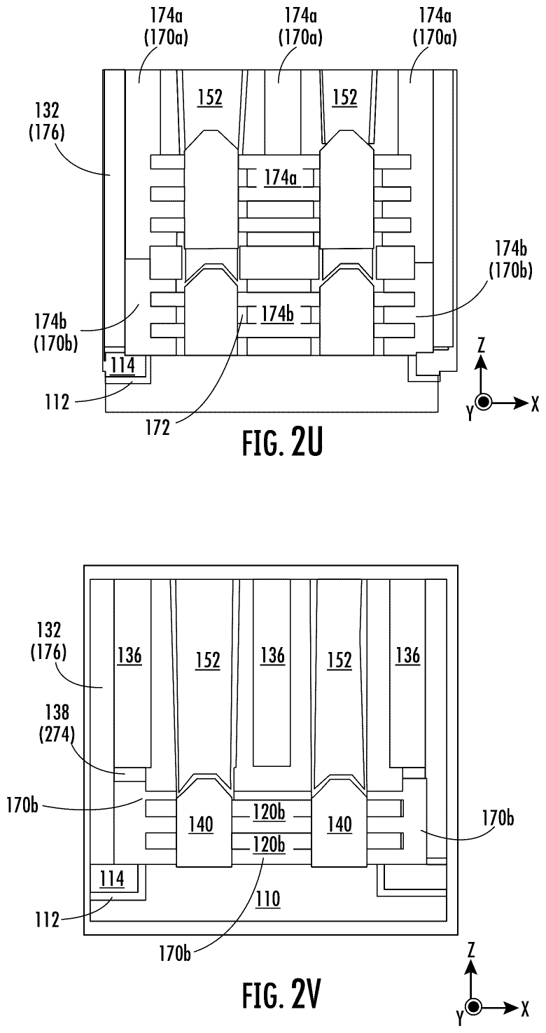

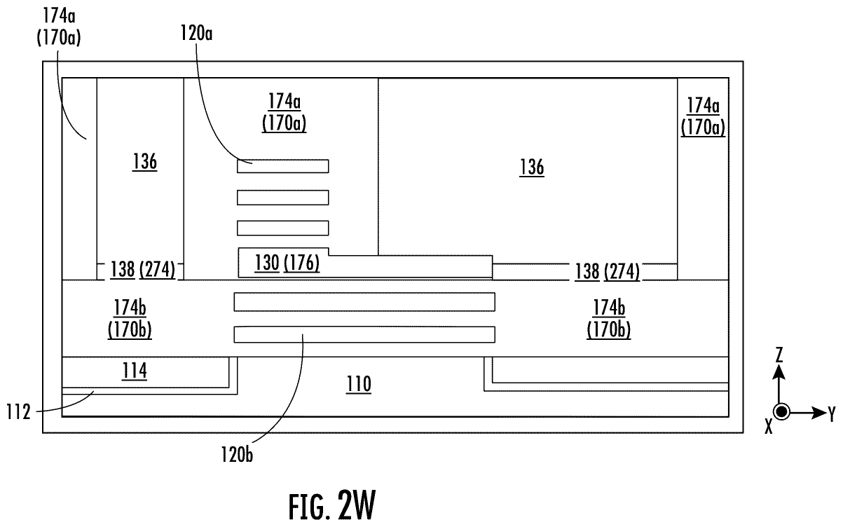

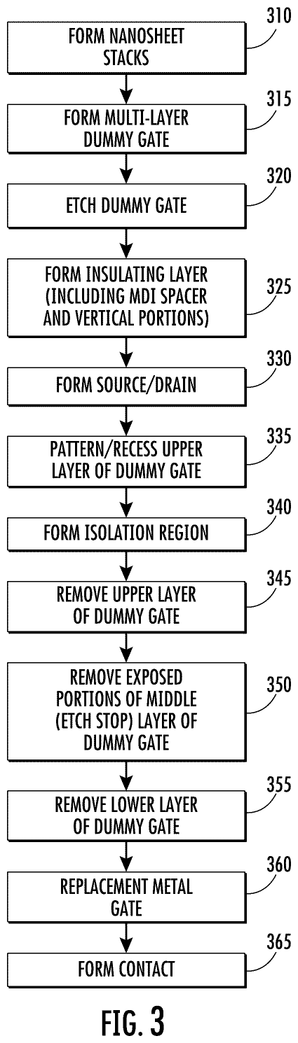

An insulating layer 138 may be vertically between an upper surface of the lower conductive gate 174b and a lower surface of the isolation region 136. As used herein, the terms “vertical” and “vertically” refer to the direction Z, which may be perpendicular to the upper surface of the lower conductive gate 174b (and to the lower surface of the isolation region 136). The insulating layer 138 may comprise, for example, the same insulating material (e.g., silicon nitride) as the insulating layers 112, 178. Moreover, the insulating layer 138 may be an intermediate (e.g., middle) layer of a multi-layer dummy gate that helps when forming the isolation region 136. As an example, the insulating layer 138 may be used as an etch-stop layer when forming a recess in the multi-layer dummy gate, where the isolation region 136 is subsequently formed in the recess. Though other layers of the multi-layer dummy gate may be removed after forming the recess, at least a portion of the insulating layer 138 may remain. Accordingly, the device 100 may include the insulating layer 138 between, in the vertical direction Z, the lower conductive gate 174b and the isolation region 136. Further details about forming the insulating layer 138 and the isolation region 136 are described herein with respect to FIGS. 2A-2W and 3.

The isolation region 136 may comprise, for example, a low-k dielectric material. As used herein, the term “low-k” refers to a material that has a smaller dielectric constant than silicon dioxide. The low-k material may include, for example, fluorine-doped silicon dioxide, organosilicate glass, carbon-doped oxide, porous silicon dioxide, porous organosilicate glass, a spin-on organic polymeric dielectric, or a spin-on silicon based polymeric dielectric.

The lower contacts 180b are taller than the upper contacts 180a (FIG. 1C), as the lower contacts 180b extend, in the vertical direction Z, to the lower transistor Tb, whereas the upper contacts 180a extend, in the vertical direction Z, to the upper transistor Ta that is on top of the lower transistor Tb. In some embodiments, a vertical length of the lower contacts 180b may be more than double a vertical length of the upper contacts 180a. The lower contacts 180b thus have larger surface areas than the upper contacts 180a, and these larger surface areas can increase the risk (and/or magnitude) of parasitic capacitances forming between the lower contacts 180b and a conventional upper gate. Because embodiments herein provide an upper gate structure 170a having the isolation region 136 therein, however, the risk (and/or magnitude) of a parasitic capacitance forming between a lower contact 180b and the upper gate structure 170a can be reduced.

For simplicity of illustration, insulating spacers 172 (FIG. 1C) are omitted from view in FIG. 1D. In some embodiments, however, the spacers 172 may be present between the lower S/D regions 140 and the conductive gate 174b in the cross-section shown in FIG. 1D.

FIG. 1E is an example cross-sectional view of the transistor device 100 along the line C-C′ of FIG. 1B. As shown in FIG. 1E, the isolation region 136 is inside (e.g., laterally bounded by) the upper conductive gate 174a. As an example, the isolation region 136 may be between, in the lateral direction Y, a pair of sidewalls of the upper conductive gate 174a. A first of the sidewalls may be part of a first portion of the upper conductive gate 174a, and a second of the sidewalls may be part of a second portion of the upper conductive gate 174a.

In some embodiments, one or more sidewalls of the isolation region 136 may contact one or more sidewalls of the upper conductive gate 174a. For example, a pair of sidewalls of the isolation region 136 may contact the pair of sidewalls of the upper conductive gate 174a. Moreover, FIG. 1E shows that the isolation region 136 may be on opposite sides, in the lateral direction Y, of the upper channel layers 120a. On each side of the upper channel layers 120a, the isolation region 136 may be separated, in the vertical direction Z, from the lower conductive gate 174b by the insulating layer 138.

The isolation region 136 may include a first portion P1 that is on an upper surface of the spacer 130, and a second portion P2 that is on an upper surface of the insulating layer 138. The first portion P1 may vertically overlap the spacer 130 and the lower channel layers 120b, and the second portion P2 may vertically overlap the insulating layer 138 and not vertically overlap the lower channel layers 120b. Rather, the second portion P2 may vertically overlap the insulating layers 112, 114. As used herein, the term “vertically overlap” refers to overlap in the vertical direction Z.

As with the second portion P2 of the isolation region 136, the insulating layer 138 may vertically overlap the insulating layers 112, 114 and may not vertically overlap the lower channel layers 120b. The insulating layer 138 may be thinner, in the vertical direction Z, than the isolation region 136. For example, an uppermost surface of the isolation region 136 may be at a vertical level that is higher than a vertical level of an uppermost surface of an uppermost one of the upper channel layers 120a. Moreover, a lowermost surface of the isolation region 136 may be at a vertical level that is lower than a vertical level of a lowermost surface of a lowermost one of the upper channel layers 120a. The insulating layer 138 may also be thinner, in the vertical direction Z, than the spacer 130.

In some embodiments, a continuous lower surface of the isolation region 136 may include the portions P1, P2. Moreover, the first portion P1 may contact the upper surface of the spacer 130, and the second portion P2 may contact the upper surface of the insulating layer 138. The portion P3 (FIG. 1D) of the isolation region 136 may be referred to herein as a “third” portion. According to some embodiments, the third portion P3 shown in FIG. 1D may be connected to (and/or may vertically overlap) the first portion P1 (and/or the second portion P2) shown in FIG. 1E, as the cross-sections shown in FIGS. 1D and 1E intersect each other.

FIG. 1E also shows that the spacer 130 may include an extension portion EP that vertically overlaps the lower channel layers 120b and is not vertically overlapped by the upper channel layers 120a. The first portion P1 of the isolation region 136 may vertically overlap the extension portion EP. In some embodiments, the lower channel layers 120b (e.g., lower nanosheets) may be wider, in the lateral direction Y, than the upper channel layers 120a (e.g., upper nanosheets). For example, the lower channel layers 120b may be more than twice as wide as the upper channel layers 120a. According to some embodiments, the spacer 130 may have the same width as the lower channel layers 120b.

Though the cross-section shown in FIG. 1E does not include the contacts 180a, 180b (FIGS. 1C, 1D), a first outline 182a depicts a shape of the upper contact 180a, and a second outline 182b depicts a shape of the lower contact 180b. The outlines 182a, 182b indicate that the upper contact 180a and the lower contact 180b are at different positions in the lateral direction Y. Moreover, the contacts 180a, 180b are spaced apart from the line C-C′ of FIG. 1B (and thus the cross-section shown in FIG. 1E) in the lateral direction X. The outline 182b thus also indicates that the contact 180b laterally overlaps the isolation region 136 in the direction X.

The size of the isolation region 136 may vary relative to the size of the contact 180b. For example, the isolation region 136 may, in some embodiments, be wider, in the direction Y, than the contact 180b. In other embodiments, the isolation region 136 may be narrower than the contact 180b. Similarly, the isolation region 136 may be taller or shorter than the contact 180b in the vertical direction Z. The isolation region 136 is thus not limited by the dimensions that are shown in FIG. 1E relative to the outline 182b of the contact 180b.

FIGS. 2A-2W are cross-sectional views illustrating operations of forming the transistor device 100 of FIGS. 1C-1E, and FIG. 3 is a flowchart corresponding to the operations shown in FIGS. 2A-2W. FIGS. 2A, 2D, 2K, 2M, 2O, 2R, and 2U are cross-sectional views corresponding to the line A-A′ of FIG. 1B. FIGS. 2B, 2E, 2G, 2I, 2P, 2S, and 2V are cross-sectional views corresponding to the line B-B′ of FIG. 1B. Moreover, FIGS. 2C, 2F, 2H, 2J, 2L, 2N, 2Q, 2T, and 2W are cross-sectional views corresponding to the line C-C′ of FIG. 1B.

As shown in FIGS. 2A-2C and 3, the operations may include forming (Block 310) stacks of semiconductor channel layers 120 on a substrate 110. In some embodiments, the channel layers 120 may be nanosheets, and the stacks may thus be nanosheet stacks. A lower stack comprises channel layers 120b, and an upper stack comprises channel layers 120a. The lower stack is separated from the upper stack by a sacrificial isolation layer 262. Moreover, sacrificial gate layers 270 may be alternately stacked on the substrate 110 with the channel layers 120. The sacrificial isolation layer 262 may be between upper ones of the sacrificial gate layers 270 and lower ones of the sacrificial gate layers 270.

The upper stack and the lower stack each form part of a transistor stack 101 (FIG. 1A). The lower channel layers 120b form part of a lower transistor Tb (FIG. 1A) of the transistor stack 101, and the upper channel layers 120a form part of an upper transistor Ta (FIG. 1A) of the transistor stack 101.

Though the plural term “stacks” is used in some examples herein for ease of differentiating between upper and lower ones of the channel layers 120, the singular term “stack” may also be used to describe the collective structure, as the upper channel layers 120a are stacked on top of the lower channel layers 120b. Accordingly, the term “nanosheet stack” may refer to either (i) a stack that includes both the upper channel layers 120a and the lower channel layers 120b, or (ii) a stack that includes one of only the upper channel layers 120a or only the lower channel layers 120b and is stacked with another stack that includes the other one of only the upper channel layers 120a or only the lower channel layers 120b.

The channel layers 120 are semiconductor layers that comprise, for example, silicon (e.g., polysilicon). In a subsequent process/operation, the sacrificial gate layers 270 may be replaced with an upper conductive gate 174a and a lower conductive gate 174b (FIG. 1C). Moreover, the sacrificial isolation layer 262 may be replaced with a spacer/MDI layer 130 (FIG. 1C) in a subsequent process/operation. The sacrificial gate layers 270 may comprise, for example, silicon germanium. Accordingly, the sacrificial gate layers 270 may have an etch selectivity relative to the channel layers 120. The sacrificial gate layers 270 may also have an etch selectivity relative to the sacrificial isolation layer 262. For example, the sacrificial isolation layer 262 and the sacrificial gate layers 270 may each comprise silicon germanium, but with different concentrations of germanium. As an example, the sacrificial isolation layer 262 may have a higher concentration of germanium (e.g., 55%) than the sacrificial gate layers 270 (e.g., 25%).

In some embodiments, an insulating layer 214 may be formed on sidewalls of the alternately-stacked channel layers 120 and sacrificial gate layers 270, and on an uppermost surface of an uppermost one of the upper channel layers 120a. Moreover, an insulating layer 112 may be formed in a recess of the substrate 110, and an insulating layer 114 may be formed in the recess on top of the insulating layer 112. The insulating layers 114, 214 may comprise the same insulating material (e.g., an oxide), and may, in some embodiments, be a single, continuous layer having no interface or separation between the insulating layers 114, 214. The insulating material of the insulating layers 114, 214 may be different from that of the insulating layer 112, which may comprise, example, a nitride (e.g., silicon nitride).

A multi-layer dummy gate structure 274 may be formed (Block 315) on the channel layers 120. The dummy gate structure 274 may include, for example, a lower sacrificial layer 272b, an upper sacrificial layer 272a, and an insulating layer 138 that is between, in the vertical direction Z, the sacrificial layers 272a, 272b. Accordingly, the dummy gate structure 274 may have three layers, and thus may be referred to herein as a “tri-layer” dummy gate structure in which the insulating layer 138 is the middle layer.

The insulating layer 138 may be on a sidewall of the sacrificial isolation layer 262. In some embodiments, the insulating layer 138 may be thinner, in the vertical direction Z, than the sacrificial isolation layer 262. The upper sacrificial layer 272a may be on top of, and on sidewalls of, the upper channel layers 120a. The lower sacrificial layer 272b may be on sidewalls of the lower channel layers 120b. The sacrificial layers 272a, 272b may each comprise a semiconductor material, and thus may be referred to herein as an “upper semiconductor sacrificial layer” and a “lower semiconductor sacrificial layer,” respectively. The semiconductor material may comprise, for example, polysilicon, and may have an etch selectivity with respect to the channel layers 120, the sacrificial gate layers 270, and/or the sacrificial isolation layer 262.

According to some embodiments, the insulating layer 214 may be between the dummy gate structure 274 and the channel layers 120. For example, the insulating layer 138, the lower sacrificial layer 272b, and the upper sacrificial layer 272a may each contact the insulating layer 214.

As shown in FIGS. 2D-2F and 3, the dummy gate structure 274 may be etched (Block 320) to form openings therein. For example, the dummy gate structure 274 may be etched to expose sidewalls of the dummy gate structure 274 and portions of an upper surface of the substrate 110. In some embodiments, the etching may be reactive-ion etching (RIE). As an example, an etch mask may be formed and patterned on an uppermost surface of the dummy gate structure 274, and then the RIE may be performed while the etch mask is in place. Moreover, the sacrificial isolation layer 262 (FIGS. 2A-2C) may be removed by performing a selective etch that leaves the sacrificial gate layers 270 between the channel layers 120.

An insulating layer/material 176 that includes an MDI spacer 130 and vertical portions 132 may be formed (Block 325) after etching the dummy gate structure 274 and the sacrificial isolation layer 262. The spacer 130 may be formed in an opening that is formed by removing the sacrificial isolation layer 262. The vertical portions 132 may be in some of the openings that are etched in the dummy gate structure 274. Moreover, lower S/D regions 140 and upper S/D regions may be formed (Block 330) in others of the openings that are etched in the dummy gate structure 274. Insulating layers 152, 178 may also be formed in the others of the openings, and insulating spacers 172 may be formed on sidewalls of the sacrificial gate layers 270 through the others of the openings.

In some embodiments, the S/D regions 140, 150 may be formed by epitaxial growth. For example, the lower S/D regions 140 may be epitaxially grown from the lower channel layers 120b, and the upper S/D regions 150 may be epitaxially grown from the upper channel layers 120a. According to some embodiments, the channel layers 120 may comprise silicon, and the lower S/D regions 140 and/or the upper S/D regions 150 may comprise silicon, silicon carbide, or silicon germanium.

The insulating layer 152 may, in some embodiments, be formed between, in the vertical direction Z, the lower and upper S/D regions 140, 150, and on an upper surface of each of the upper S/D regions 150. According to some embodiments, a planarization operation/process (e.g., chemical-mechanical planarization (CMP)) may be performed after forming the insulating layers 132, 152. Moreover, the insulating layers 132, 134 may comprise the same insulating material (e.g., SiBCN) as the spacer 130, and this insulating material may be different from that of the insulating layers 152, 214 (e.g., an oxide).

In some embodiments, the insulating spacers 172 may be formed on sidewalls of the sacrificial gate layers 270 and between, in the vertical direction Z, the channel layers 120. For example, the sacrificial gate layers 270 may be etched to form openings in the sacrificial gate layers 270 between the channel layers 120. Sidewalls of the sacrificial gate layers 270 may be exposed through the openings, and the spacers 172 may be formed in the openings. The spacers 172 may comprise the same insulating material (e.g., silicon nitride) as the insulating layers 112, 178, which may be different from the insulating material of the insulating layer 152 and different from the insulating material of the insulating layers 132, 134.

As shown in FIGS. 2G, 2H, and 3, the upper sacrificial layer 272a may be patterned/recessed (Block 335) to form openings 276, 278. The openings 276 may remove the upper sacrificial layer 272a from between sidewalls of the vertical portions 132, and may thereby expose the sidewalls of the vertical portions 132. The openings 278 may expose portions of an upper surface of the insulating layer 138, and may expose an upper surface of an extension portion EP of the spacer 130, where the extension portion EP is not vertically overlapped by the upper channel layers 120a. Each opening 276, 278 may also be referred to herein as a “recess” in the upper sacrificial layer 272a. In some embodiments, an opening 276 (e.g., the middle/second opening) shown in FIG. 2G may be connected to (and/or may vertically overlap) an opening 278 shown in FIG. 2H, as the cross-sections shown in FIGS. 2G and 2H intersect each other.

As shown in FIGS. 2I, 2J, and 3, an isolation region 136 may be formed (Block 340) in the openings 276 (FIG. 2G) and the openings 278 (FIG. 2H). The isolation region 136 may thus be formed (i) between the vertical portions 132, (ii) on the exposed portions of the insulating layer 138, and (iii) on the exposed upper surface of the extension portion EP of the spacer 130. The vertical portions 132 may extend longitudinally in the direction Z, which may be perpendicular to the exposed upper surface of the extension portion EP (and to an exposed upper surface of an etch-stop layer provided by the insulating layer 138). The isolation region 136 may be formed by, for example, filling the openings 276, 278 with a low-k material and then planarizing the low-k material, such as by CMP. After the CMP, an uppermost surface of the isolation region 136 may be coplanar with uppermost surfaces of portions of the upper sacrificial layer 272a that remain after forming the openings 276, 278.

As shown in FIGS. 2K, 2L, and 3, the remaining portions of the upper sacrificial layer 272a may be removed (Block 345). As an example, a polysilicon removal process may be performed using the insulating layer 138 as an etch-stop layer. The removal process may form openings 284 that expose sidewalls of the vertical portions 132. Moreover, the removal process may form openings 286 that expose an upper surface of an uppermost one of the upper channel layers 120a, and portions of upper surfaces of the insulating layer 138 and the spacer 130. The openings 286 may also expose sidewalls of the upper channel layers 120, and sidewalls of the sacrificial gate layers 270 that are between the upper channel layers 120.

As shown in FIGS. 2M, 2N, and 3, exposed portions of the insulating layer 138 may be removed (Block 350) through the openings 284, 286. As a result, portions of upper surfaces of the lower sacrificial layer 272b may be exposed. The insulating layer 138 may be etched using, for example, an etch process that has an etch selectivity with respect to the isolation region 136 and the insulating layer 214.

As shown in FIGS. 2O-2Q and 3, the lower sacrificial layer 272b may be removed (Block 355). For example, the lower sacrificial layer 272b may be removed through the openings 284, 286. As a result, further openings 288, 290 may be formed that expose lower surfaces of the insulating layer 138 and sidewalls of the insulating layers 132, 214. In some embodiments, the lower sacrificial layer 272b may be removed by performing a polysilicon removal process.

As shown in FIGS. 2R-2T, the sacrificial gate layers 270 may be removed from between the channel layers 120, as the sacrificial gate layers 270 may have an etch selectivity relative to the channel layers 120. Removal of the sacrificial gate layers 270 forms openings 292 between the channel layers 120. Moreover, the insulating layer 214 may be removed from sidewalls of the lower channel layers 120b, and from sidewalls of the spacer 130. As an example, the insulating layer 214 may be removed by an extra gate (EG) oxide removal operation/process. Removal of the insulating layer 214 forms openings 294 that are between the openings 288 and the sidewalls of the channel layers 120. The openings 294 may expose the sidewalls of the channel layers 120, and portions of the sidewalls of the spacer 130.

In some embodiments, a portion of the insulating layer 214 may be between a sidewall of the insulating layer 138 and a sidewall of the spacer 130, and may be removed by the EG oxide removal operation/process. In other embodiments, the portion of the insulating layer 214 may not be removed by the EG oxide removal operation/process, and thus may remain between the sidewall of the insulating layer 138 and the sidewall of the spacer 130. In still other embodiments, the sidewall of the insulating layer 138 may contact the sidewall of the spacer 130, and therefore may not be separated from the sidewall of the spacer 130 by another layer/material.

As shown in FIGS. 2U-2W, conductive gates 174a, 174b may be formed. For example, the lower conductive gate 174b may be formed by forming a lower metal layer in the openings 288, 290, and 294, lower portions of the openings 284, and ones of the openings 292 that are between the lower channel layers 120b. Moreover, the upper conductive gate 174a may be formed by forming an upper metal layer in the openings 286, upper portions of the openings 284, and ones of the openings 292 that are between the upper channel layers 120a. In some embodiments, the lower metal layer may comprise a first metal, and the upper metal layer may comprise a second metal that is different from the first metal. Though omitted from view in FIGS. 2U-2W for simplicity of illustration, gate insulation layers may, according to some embodiments, be formed between each metal layer and the channel layers 120.

The operations shown in FIGS. 2R-2W may each be part of a replacement-metal-gate (RMG) process (Block 360 of FIG. 3) that is performed after forming the S/D regions 140, 150 and after removing the upper and lower sacrificial layers 272a, 272b of the multi-layer dummy gate structure 274. The metal layers of the conductive gates 174a, 174b may replace not only the sacrificial gate layers 270, but also the upper and lower sacrificial layers 272a, 272b. Moreover, the isolation region 136 is inside the upper conductive gate 174a, and thus can help to reduce a parasitic capacitance between the upper conductive gate 174a and a tall (i.e., high aspect ratio) conductive contact, which is formed after forming the upper conductive gate 174a.

As shown in FIGS. 1C, 1D, and 3, upper and lower conductive contacts 180a, 180b may be formed (Block 365) that are electrically connected to the upper transistor Ta and the lower transistor Tb. For example, the contacts 180a, 180b may be formed in the insulating layer 152 and may be electrically connected the upper and lower S/D regions 150, 140, respectively. In some embodiments, a pair of the upper contacts 180a may be in contact with upper surfaces of a pair of the upper S/D regions 150, respectively, and a pair of the lower contacts 180b may be in contact with upper surfaces of a pair of the lower S/D regions 140, respectively. According to some embodiments, the upper contacts 180a may comprise the same metal as the lower contacts 180b. Moreover, the lower contacts 180b may be taller (i.e., have higher aspect ratios) than the upper contacts 180a.

Transistor devices 100 (FIG. 1A) according to embodiments herein may provide a number of advantages. These advantages include reducing the risk (and/or magnitude) of a parasitic capacitance forming between a lower conductive contact 180b (FIG. 1D) and an upper gate structure 170a (FIG. 1E) because the upper gate structure 170a includes an isolation region 136 (FIG. 1E). The reduced parasitic capacitance can improve performance of the devices 100. Moreover, the isolation region 136 may be formed in openings 276, 278 (FIGS. 2G, 2H) that are formed by a controllable vertical recess operation for a multi-layer dummy gate structure 274 (FIG. 2H). For example, the dummy gate structure 274 may include an insulating layer 138 (FIG. 2H) that serves as an etch-stop layer when forming the openings 276, 278 in the dummy gate structure 274. The insulating layer 138 can thus reduce a process variation when forming the openings 276, 278, and can protect lower channel layers 120b (FIG. 2H) from damage that may otherwise occur when forming the openings 276, 278 (e.g., damage that may occur if the openings 276, 278 were instead formed deeper than intended because they were not stopped by an etch-stop layer).

Example embodiments are described herein with reference to the accompanying drawings. Many different forms and embodiments are possible without deviating from the teachings of this disclosure and so the disclosure should not be construed as limited to the example embodiments set forth herein. Rather, these example embodiments are provided so that this disclosure will be thorough and complete, and will convey the scope of the present invention to those skilled in the art. In the drawings, the sizes and relative sizes of layers and regions may be exaggerated for clarity. Like reference numbers refer to like elements throughout.

Example embodiments are described herein with reference to cross-sectional illustrations that are schematic illustrations of idealized embodiments and intermediate structures of example embodiments. As such, variations from the shapes of the illustrations as a result, for example, of manufacturing techniques and/or tolerances, are to be expected. Thus, embodiments herein should not be construed as limited to the particular shapes illustrated herein but may include deviations in shapes that result, for example, from manufacturing.

It should also be noted that in some alternate implementations, the functions/acts noted in flowchart blocks herein may occur out of the order noted in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Finally, other blocks may be added/inserted between the blocks that are illustrated, and/or blocks/operations may be omitted without departing from the scope of the present invention.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of the stated features, steps, operations, elements, and/or components, but do not preclude the presence or addition of one or more other features, steps, operations, elements, components, and/or groups thereof.

It will be understood that when an element is referred to as being “coupled,” “connected,” or “responsive” to, or “on,” another element, it can be directly coupled, connected, or responsive to, or on, the other element, or intervening elements may also be present. In contrast, when an element is referred to as being “directly coupled,” “directly connected,” or “directly responsive” to, or “directly on,” another element, there are no intervening elements present. As used herein, the term “and/or” includes any and all combinations of one or more of the associated listed items. Moreover, the symbol “/” (e.g., when used in the term “source/drain”) will be understood to be equivalent to the term “and/or.”

It will be understood that although the terms “first,” “second,” etc. may be used herein to describe various elements, these elements should not be limited by these terms. These terms are only used to distinguish one element from another. Thus, a first element could be termed a second element without departing from the teachings of the present embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is turned over, elements described as “below” or “beneath” other elements or features would then be oriented “above” the other elements or features. Thus, the term “below” can encompass both an orientation of above and below. The device may be otherwise oriented (e.g., rotated 90 degrees or at other orientations) and the spatially relative descriptors used herein may be interpreted accordingly.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

The above-disclosed subject matter is to be considered illustrative, and not restrictive, and the appended claims are intended to cover all such modifications, enhancements, and other embodiments, which fall within the scope of the present invention. Thus, to the maximum extent allowed by law, the scope is to be determined by the broadest permissible interpretation of the following claims and their equivalents, and shall not be restricted or limited by the foregoing detailed description.

What is claimed is:

1. A stacked field-effect transistor (FET) device comprising:
a lower FET comprising lower channel layers, a lower gate structure that is between the lower channel layers, and a lower source/drain (S/D) region that is electrically connected to the lower channel layers;
an S/D contact that is electrically connected to the lower S/D region;
an upper FET that is on top of the lower FET, the upper FET comprising upper channel layers, an upper gate structure that is between the upper channel layers, and an upper S/D region that is electrically connected to the upper channel layers, wherein the upper gate structure comprises a conductive gate and an isolation region that is inside the conductive gate and on a sidewall of the S/D contact;
a spacer that separates the upper channel layers from the lower channel layers; and
an insulating layer that is between a lower surface of the isolation region and an upper surface of the lower gate structure.

2. The stacked FET device of claim 1, wherein the insulating layer does not vertically overlap the lower channel layers in a vertical direction that is perpendicular to the upper surface of the lower gate structure.

3. The stacked FET device of claim 1, wherein a sidewall of the conductive gate is in contact with a sidewall of the isolation region.

4. The stacked FET device of claim 1,
wherein the insulating layer is thinner, in a vertical direction, than the spacer,
wherein the insulating layer is thinner, in the vertical direction, than the isolation region, and
wherein the vertical direction is perpendicular to the upper surface of the lower gate structure.

5. The stacked FET device of claim 1, wherein the lower surface of the isolation region comprises:
a first portion that is on an upper surface of the spacer; and
a second portion that is on an upper surface of the insulating layer.

6. The stacked FET device of claim 1, wherein the isolation region comprises:
a first portion that vertically overlaps the spacer and the lower channel layers in a vertical direction that is perpendicular to the upper surface of the lower gate structure; and
a second portion that vertically overlaps the insulating layer in the vertical direction and does not vertically overlap the lower channel layers in the vertical direction.

7. The stacked FET device of claim 6,
wherein the spacer is a lateral portion of a first insulating material,
wherein the insulating layer comprises a second insulating material that is different from the first insulating material,
wherein the isolation region comprises a third insulating material that is different from the first insulating material and different from the second insulating material,
wherein a vertical portion of the first insulating material is between, in a lateral direction that is perpendicular to the vertical direction, a third portion of the isolation region and the sidewall of the S/D contact, and
wherein the vertical portion of the first insulating material extends longitudinally in the vertical direction.

8. The stacked FET device of claim 7, wherein the third portion of the isolation region is between, in the lateral direction, the vertical portion of the first insulating material and a second vertical portion of the first insulating material.

9. The stacked FET device of claim 8, further comprising:
a second lower S/D region that is electrically connected to the lower channel layers; and
a second S/D contact that is electrically connected to the second lower S/D region,
wherein the third portion of the isolation region, the vertical portion of the first insulating material, and the second vertical portion of the first insulating material are between, in the lateral direction, the S/D contact and the second S/D contact.

10. The stacked FET device of claim 9, wherein the conductive gate is not between the S/D contact and the second S/D contact.

11. The stacked FET device of claim 1, wherein the isolation region has a lower dielectric constant than the insulating layer.

12. The stacked FET device of claim 11, wherein the insulating layer is an etch-stop layer that comprises silicon nitride.

13. The stacked FET device of claim 1, wherein the conductive gate comprises a first conductive material that is different from a second conductive material of the lower gate structure.

14. A stacked field-effect transistor (FET) device comprising:
a lower FET comprising lower channel layers and a lower gate structure that is between the lower channel layers;
a contact that is electrically connected to the lower FET;
an upper FET that is on top of the lower FET, the upper FET comprising upper channel layers and an upper gate structure that is between the upper channel layers, wherein the upper gate structure comprises a conductive gate and an isolation region that is between a first portion and a second portion of the conductive gate and on a sidewall of the contact;
a spacer that separates the upper channel layers from the lower channel layers; and
an insulating layer that is between a lower surface of the isolation region and an upper surface of the lower gate structure.

15. The FET device of claim 14,
wherein the contact is a first contact among a pair of source/drain (S/D) contacts that are electrically connected to a pair of S/D regions, respectively, of the lower FET, and
wherein the isolation region is between the pair of S/D contacts.

16. A method of forming a stacked field-effect transistor (FET) device, the method comprising:
forming a nanosheet stack and a multi-layer dummy gate structure on the nanosheet stack, wherein the multi-layer dummy gate structure comprises a lower semiconductor sacrificial layer, an upper semiconductor sacrificial layer, and an etch-stop layer that is between the lower semiconductor sacrificial layer and the upper semiconductor sacrificial layer;
etching the upper semiconductor sacrificial layer to expose sidewalls of the upper semiconductor sacrificial layer;
forming a first insulating layer comprising vertical portions on the exposed sidewalls of the upper semiconductor sacrificial layer and a lateral portion between upper nanosheets of the nanosheet stack and lower nanosheets of the nanosheet stack;
patterning the upper semiconductor sacrificial layer by removing a portion of the upper semiconductor sacrificial layer that is between the vertical portions of the first insulating layer and exposing an upper surface of the etch-stop layer, wherein the etch-stop layer comprises a second insulating layer;
forming an isolation region between the vertical portions of the first insulating layer and on the exposed upper surface of the etch-stop layer; and
forming a contact on a sidewall of one of the vertical portions of the first insulating layer,
wherein the vertical portions of the first insulating layer extend longitudinally in a vertical direction that is perpendicular to the exposed upper surface of the etch-stop layer.

17. The method of claim 16, further comprising, after forming the isolation region:
removing the upper semiconductor sacrificial layer; then
removing the lower semiconductor sacrificial layer; then
forming a lower conductive gate between the lower nanosheets and forming an upper conductive gate between the upper nanosheets,
wherein the etch-stop layer is on an upper surface of the lower conductive gate.

18. The method of claim 17, wherein removing the upper semiconductor sacrificial layer comprises exposing a portion of the etch-stop layer that is not vertically overlapped by the isolation region in the vertical direction.

19. The method of claim 17, further comprising forming source/drain regions that are electrically connected to the lower nanosheets, before forming the lower conductive gate,
wherein forming the contact comprises forming a pair of contacts that are electrically connected to the source/drain regions, respectively, after forming the isolation region.

20. The method of claim 16,
wherein the lower nanosheets are wider than the upper nanosheets,
wherein the lateral portion of the first insulating layer comprises a spacer having an extension portion that vertically overlaps the lower nanosheets in the vertical direction and is not vertically overlapped by the upper nanosheets in the vertical direction,
wherein patterning the upper semiconductor sacrificial layer comprises exposing an upper surface of the extension portion of the spacer, and
wherein forming the isolation region comprises forming the isolation region on the exposed upper surface of the extension portion of the spacer.
